(19) United States
(12) Patent Application Publication
(10) Pub. No.: US 2006/0162850 A1
(43) Pub. Date: Jul. 27, 2006

(54) Methods and apparatus for releasably attaching microfeature workpieces to support members

(75) Inventors: Rickie C. Lake, Meridian, ID (US); Charles M. Watkins, Eagle, ID (US)

Correspondence Address: PERKINS COIE LLP;PATENT-SEA, PO BOX 1247, SEATTLE, WA, 98111-1247, US

(73) Assignee: Micron Technology, Inc., Boise, ID (US)

(21) Appl. No.: 11/042,749

(22) Filed: Jan. 24, 2005

(51) Int. Cl. H01L 21/302; B32B 37/00

(52) U.S. Cl. 156/153; 438/689; 156/248

(57) ABSTRACT

Methods and apparatuses for releasably attaching microfeature workpieces to support members are disclosed herein. In one embodiment, a method includes applying a first material to a first region on a first side of a microfeature workpiece. The method then includes releasably attaching the first side of the workpiece to a support member. The method further includes applying a second material to a second region on the first side of the workpiece. The second region includes a perimeter portion of the workpiece. The first material and/or the second material can be an adhesive. The second material is removable from the workpiece relative to the first material. In several embodiments, for example, the first material can have a first solubility in a solution and the second material can have a second solubility in the solution less than the first solubility.

### TECHNICAL FIELD

The present invention is related to methods and apparatuses for releasably attaching microfeature workpieces to support members.

### BACKGROUND

Existing microelectronic device packages typically include a microelectronic die attached to a support member, such as a printed circuit board. Bond-pads or other terminals on the die are electrically connected to corresponding terminals on the support member with solder balls, wire bonds, or other types of connectors. The connection between the die and the support member can be protected by encapsulating the die to form a device package. The package can then be electrically connected to other microelectronic devices or circuits in many types of consumer or industrial electronic products.

Manufacturers are under continuous pressure to reduce the size of the electronic products. Accordingly, microelectronic die manufacturers seek to reduce the size of the package dies incorporated into the electronic products. The height of the packaged dies is often reduced by grinding the backside of the wafer to thin the dies before singulating the wafer and encapsulating the dies. One drawback with this approach, however, is that thin wafers are extremely fragile and therefore difficult to handle.

One approach for addressing this drawback is to attach a relatively thick wafer support to the wafer during the grinding process to ensure survival of the wafer as well as to facilitate handling of the wafer during processing. One system, for example, includes attaching a wafer to a wafer support using a light-activated adhesive. The wafer support is then removed after the wafer is processed and the resulting thin wafer is ready for further processing and/or packaging.

This system, however, has several drawbacks. One drawback is that the wafer support and attached wafer do not have the form factor of a typical microfeature workpiece (e.g., approximately 750 μm thick). More specifically, the wafer support and attached wafer are substantially thicker than 750 μm and do not fit into semiconductor processing equipment having a form factor for 750 μm thick workpieces. Another drawback of this system is that subsequent processing steps using lasers can break the bond of the light-activated adhesive. As a result, the wafers may become unstable and/or completely break away from the wafer support.

Because of the problems with the light-activated adhesive described above, a variety of other adhesives have been used to attach the wafer to the wafer support. However, there are drawbacks with using such other adhesives. For example, if an adhesive with a low melting point is used, the subsequent processing steps cannot involve high temperatures. Moreover, if a water-soluble adhesive is used, the adhesive may become unstable during backgrinding processes or other processes that use aqueous solutions. Accordingly, there is a need to improve the handling of microfeature workpieces during processing.

### BRIEF DESCRIPTION OF THE DRAWINGS

FIGS. 1A-1G illustrate various stages of a method for releasably attaching a microfeature workpiece to a support member in accordance with an embodiment of the invention.

FIG. 1A is a top plan view of a microfeature workpiece after a first adhesive has been deposited onto the workpiece.

FIG. 1B is a side cross-sectional view of the microfeature workpiece taken substantially along line 1B-1B of FIG. 1A.

FIG. 1C is a schematic side cross-sectional view of the microfeature workpiece releasably attached to a support member to form a microfeature assembly.

FIG. 1D is a side cross-sectional view of the microfeature assembly after application of a second adhesive to a perimeter portion of the microfeature workpiece.

FIG. 1E is a top plan view of the microfeature workpiece taken substantially along line 1E-1E of FIG. 1D.

FIG. 1F is a partially schematic isometric view of the microfeature assembly of FIG. 1D including a cut-away portion.

FIG. 1G is a side cross-sectional view of the microfeature assembly after further processing of the microfeature workpiece.

FIG. 2 is a top plan view of a microfeature workpiece after an adhesive material has been deposited onto the workpiece in accordance with another embodiment of the invention.

FIG. 3 is a top plan view of a microfeature workpiece after an adhesive material has been deposited onto the workpiece in accordance with still another embodiment of the invention.

FIG. 4 is a top plan view of a microfeature workpiece after an adhesive material has been deposited onto the workpiece in accordance with yet another embodiment of the invention.

### DETAILED DESCRIPTION

A. Overview

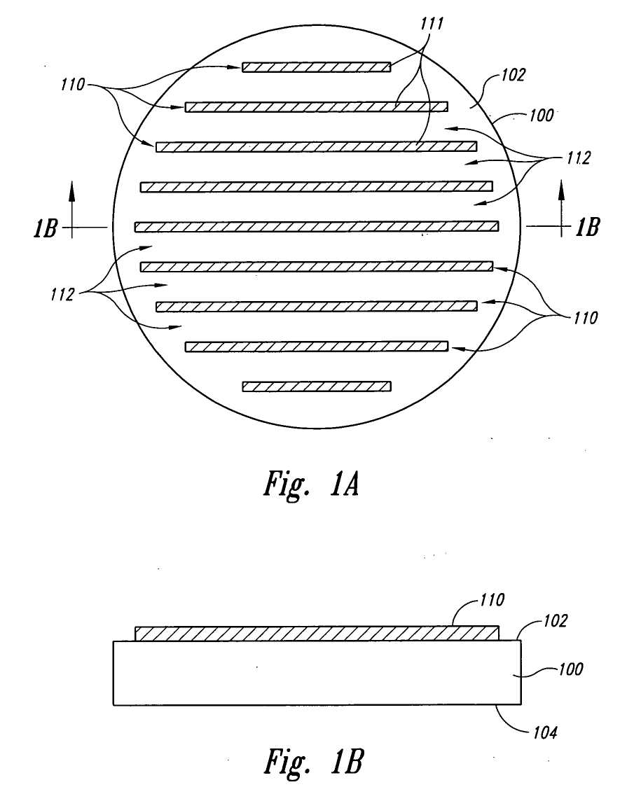

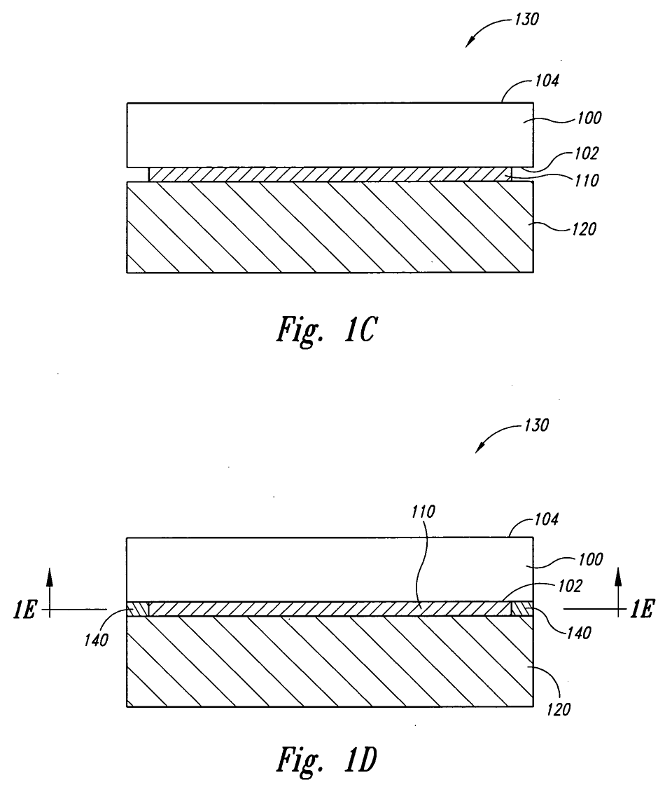

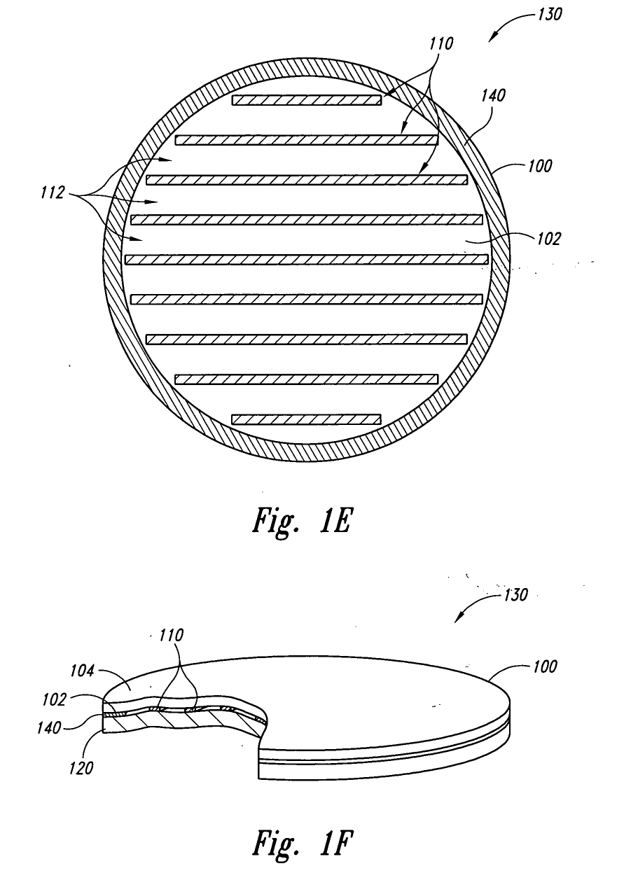

The present invention is directed toward methods and apparatuses for releasably attaching microfeature workpieces to support members. The term “microfeature workpiece” is used throughout to include substrates upon which and/or in which microelectronic devices, micromechanical devices, data storage elements, read/write components, and other devices are fabricated. For example, microfeature workpieces can be semiconductor wafers (e.g., silicon or gallium arsenide wafers), dielectric substrates (e.g., glass or ceramic), and many other types of materials. Microfeature workpieces typically have submicron features with dimensions of 0.05 μm or greater. Several embodiments in accordance with the invention are set forth in FIGS. 1A-4 and the following text to provide a thorough understanding of particular embodiments of the invention. A person skilled in the art will understand, however, that the invention may have additional embodiments, or that the invention may be practiced without several of the details of the embodiments shown in FIGS. 1A-4.

Several aspects of the invention are directed to methods for processing microfeature workpieces. In one embodiment, a method includes applying a first material to a first region on a first side of a microfeature workpiece. The method then includes releasably attaching the first side of the workpiece to a support member. The method further includes applying a second material to a second region on the first side of the workpiece. The second region includes a perimeter portion of the workpiece. The first material and/or the second material can be an adhesive. The second material is removable from the workpiece relative to the first material. In several embodiments, for example, the first material can have a first solubility in a solution and the second material can have a second solubility in the solution less than the first solubility.

A method in accordance with another aspect of the invention includes depositing an adhesive material onto a microfeature workpiece in a pattern. The pattern of adhesive material includes a first portion and a second portion spaced apart from each other by a channel. The method continues by releasably attaching the workpiece to a support member such that the adhesive is at least partially between the support member and the workpiece. The method can further include removing at least a portion of the workpiece from the support member after processing the workpiece.

Another aspect of the invention is directed to a microfeature assembly. In one embodiment, the microfeature assembly includes a microfeature workpiece having a first side and a second side facing opposite from the first side. The first side of the workpiece includes a first region and a second region. The assembly can also include a first material on at least a portion of the first region of the workpiece. The first material has a first solubility in a solution. The assembly also includes a second material on at least a portion of the second region of the workpiece. The second region includes a perimeter portion of the workpiece such that the second material substantially seals the first material from an outside environment. In one aspect of this embodiment, the second material has a second solubility in the solution less than the first solubility. The first material and/or the second material is an adhesive. The assembly further includes a support member carried by the first side of the workpiece.

B. Systems and Methods for Releasably Attaching a Microfeature Workpiece to a Support Member

FIGS. 1A-1G illustrate stages in one embodiment of a method for releasably attaching a microfeature workpiece to a support member. More specifically, FIGS. 1A-1G illustrate a method for releasably attaching a workpiece to a support member using the combination of a first adhesive at an inner portion of the workpiece and a second adhesive at a perimeter portion of the workpiece to protect the first adhesive from an outside environment during processing.

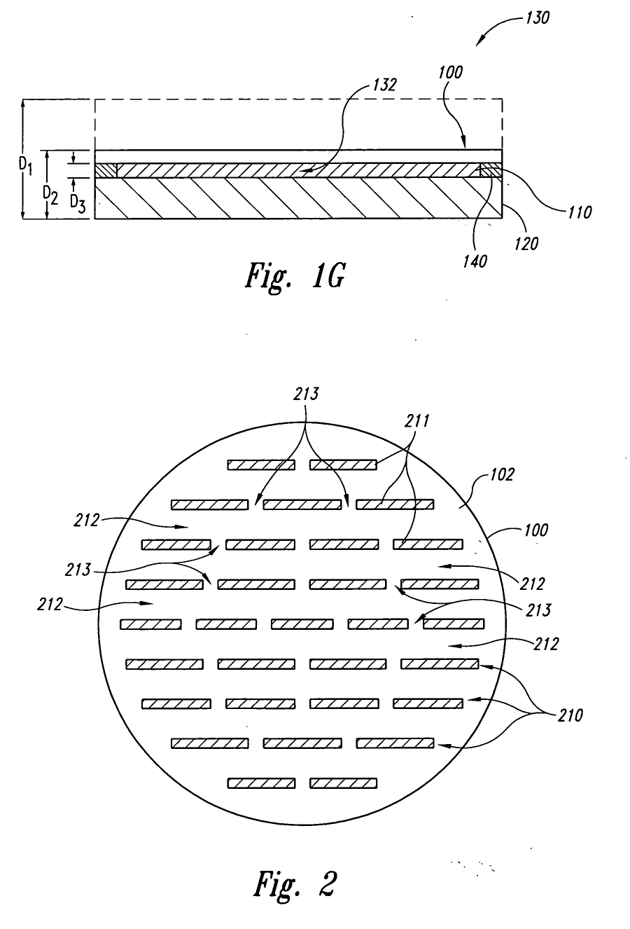

FIG. 1A is a top plan view of a microfeature workpiece 100 at an initial stage before the workpiece 100 has been attached to a support member, and FIG. 1B is a side cross-sectional view taken substantially along line 1B-1B of FIG. 1A. Referring to FIGS. 1A and 1B together, the workpiece 100 includes a first side 102 and a second side 104 (FIG. 1B) facing opposite the first side 102. The workpiece 100 in the illustrated embodiment also includes a first adhesive material 110 deposited onto at least a portion of the first side 102 of the workpiece 100. As shown in FIG. 1A, the first adhesive 110 can be deposited onto the first side 102 of the workpiece 100 in a plurality of generally parallel rows 111 separated by channels 112. The channels 112 provide pathways to the central region of the workpiece 100 allowing a solvent to quickly remove the first adhesive 110 from the workpiece 100 at a later stage. In additional embodiments described below with respect to FIGS. 2-4, the first adhesive 110 may be deposited onto the workpiece 100 in different patterns or, alternatively, the first adhesive 110 may be deposited onto the workpiece 100 as a generally uniform film without channels. The first adhesive 110 can be deposited onto the workpiece 100 using a pen-type dispensing process. In other embodiments, however, the first adhesive 110 can be deposited onto the workpiece 100 using a screen printing process or another method known to those of skill in the art.

The physical and/or chemical properties of the first adhesive 110 are based on the environments in which the workpiece 100 will be processed while it is attached to the workpiece holder. In particular embodiments, the first adhesive 110 is a material that may be removed from the workpiece 100 using a first solution (e.g., an aqueous solution or other type of solution). As discussed in greater detail below, the material of the first adhesive 110 affects the choice of material for the second adhesive that protects the first adhesive 110 during processing. In several embodiments, the first adhesive 110 can include Staystik® commercially available from Cookson Electronics of Alpharetta, Ga., or GenTak 230 commercially available from General Chemical Corporation of Parsippany, N.J. In other embodiments, however, the first adhesive 110 may include other water-soluble materials or materials that have a low solubility in water.

Referring next to FIG. 1C, the workpiece 100 is attached to a support member 120 (e.g., a carrier substrate) to form a microfeature assembly 130. The workpiece 100 is generally positioned relative to the support member 120 such that the first side 102 of the workpiece 100 faces toward the support member 120. Accordingly, the first adhesive 110 is between the first side 102 of the workpiece 100 and the support member 120 to releasably connect the workpiece 100 to the support member 120. The support member 120 can be sized and shaped to receive the workpiece 100 and provide support to the workpiece 100 during subsequent processing steps to prevent the workpiece 100 from breaking and/or excessively warping. In one embodiment, the support member 120 is generally rigid and has a planform shape at least approximately identical to that of the workpiece 100. In alternative embodiments, however, the support member 120 may be slightly larger than the workpiece 100 to avoid the need for precisely aligning the workpiece 100 with the support member 120 when attaching the two together and for protecting the edge of the workpiece 100 after thinning.

FIG. 1D is a side cross-sectional view of the assembly 130 at a subsequent stage of processing the workpiece 100, and FIG. 1E is a top plan view of the workpiece taken along line 1E-1E of FIG. 1D. Referring to FIGS. 1D and 1E together, a second material 140 is deposited around a perimeter portion of the workpiece 100 and/or the support member 120 such that the second material 140 substantially seals the first adhesive 110 from an outside environment. In the illustrated embodiment, for example, a bead of second material 140 is deposited onto the perimeter portion of the workpiece 100 and fills the gap between the support member 120 and the workpiece 100. In several embodiments, the second material 140 is a second adhesive 140, but in alternative embodiments the second material can be a suitable nonadhesive material. The second adhesive 140 can be applied using an edge dispense method, a screen printing method, or a caulking method. In alternative embodiments, the second adhesive 140 may be deposited onto the assembly 130 using other methods known to those of skill in the art.

The second adhesive 140 has physical and/or chemical properties such that the second adhesive 140 is selectively removable from the workpiece 100 relative to the first adhesive 110. For example, the first adhesive 110 can have a first solubility in water and the second adhesive 140 can have a second solubility in water less than the first solubility. Alternatively, the first solubility of the first adhesive 110 can be greater than the second solubility of the second adhesive 140 in water or another solution. When the workpiece is to be processed in aqueous solutions while attached to a workpiece holder for thinning or other purposes, the second adhesive 140 is generally substantially insoluble or otherwise water-resistant and the first adhesive 120 is generally water-soluble. One advantage of this arrangement is that the second adhesive 140 is a barrier that protects the first adhesive 110 from processing chemicals (e.g., planarizing solution) that would affect the first adhesive 110.

FIG. 1F is a partially schematic isometric view of the assembly 130 of FIG. 1D, including a cut-away portion. After the second adhesive 140 has been deposited around the perimeter of the workpiece 100, the workpiece is ready for additional processing. In one embodiment, the additional processing can include removing material from the second side 104 of the workpiece 100 to reduce its thickness. For example, the material can be removed from the second side 104 by grinding and/or etching the workpiece 100. In other embodiments, the material can be removed from the second side 104 using other processes.

FIG. 1G is a side cross-sectional view of the assembly 130 after the workpiece 100 has been thinned. The assembly 130 has been thinned from a first thickness D₁ to a second thickness D₂. In the illustrated embodiment, the workpiece 100 has been thinned from approximately 750 μm to approximately 100 μm, but in other embodiments the workpiece 100 may have a different post-processing thickness.

In one aspect of this embodiment, the thickness D₃ of an adhesive layer 132 (e.g., the first adhesive 110) is formed so that the overall thickness D₂ of the assembly 130 has a desired thickness for further processing of the workpiece in the normal form factor of the processing equipment. In most cases, the thicknesses of the workpiece 100 and/or the support member 120 are generally constant after thinning. As such, by controlling the thickness of the adhesive layer 132, the aggregate thickness of the assembly 130 can be suitable for the form factor (e.g., approximately 750 μm) of the semiconductor processing equipment used for subsequent processing of the workpiece 100. After processing of the workpiece 100 is complete, the second adhesive 140 can be removed from the workpiece 100. The first adhesive 110 can then be removed from the workpiece 100, thus releasing the workpiece 100 from the support member 120, and the workpiece 100 can undergo further packaging and/or processing steps.

Another feature of the embodiments described above with respect to FIGS. 1A-1G is that the channels separating the individual portions of adhesive material on the workpiece 100 provide a flow path across the workpiece 100 for a solvent that removes the first adhesive 110 from the workpiece. As described above, for example, a solvent can readily flow through the channels 112 between the various portions of the first adhesive 110 on the workpiece 100 to quickly remove-the first adhesive 110 from the workpiece. Moreover, less of the first adhesive 110 is deposited onto the workpiece 100 in the pattern shown above in FIG. 1A and the patterns described below with respect to FIGS. 2-4 compared to conventional processes that coat the entire surface of the workpiece with an adhesive. Accordingly, less solvent and less time are necessary to remove the adhesive material from the workpiece compared to conventional adhesive configurations.

C. Additional Embodiments of Methods for Depositing Adhesive Material Onto Microfeature Workpieces

FIGS. 2-4 illustrate three alternative embodiments of methods for depositing adhesive material onto microfeature workpieces as described above with respect to FIGS. 1A and 1B. In each of FIGS. 2-4, several of the features may be the same as those discussed above in connection with the workpiece 100 of FIGS. 1A and 1B. Accordingly, like reference numbers refer to like components in FIG. 1A and 1B and FIG. 2-4.

FIG. 2 is a top plan view of the first side 102 of the workpiece 100 after a first adhesive material 210 has been deposited onto the workpiece 100 in accordance with an embodiment of the invention. The first adhesive 210 differs from the first adhesive 110 shown in FIGS. 1A and 1B in that the first adhesive 210 is configured into rows of adhesive blocks 211. The rows of adhesive 210 are separated by channels 212, and the blocks 211 in a row are separated by gaps 213. Each row of adhesive material 210, for example, generally has at least two adhesive blocks 211.

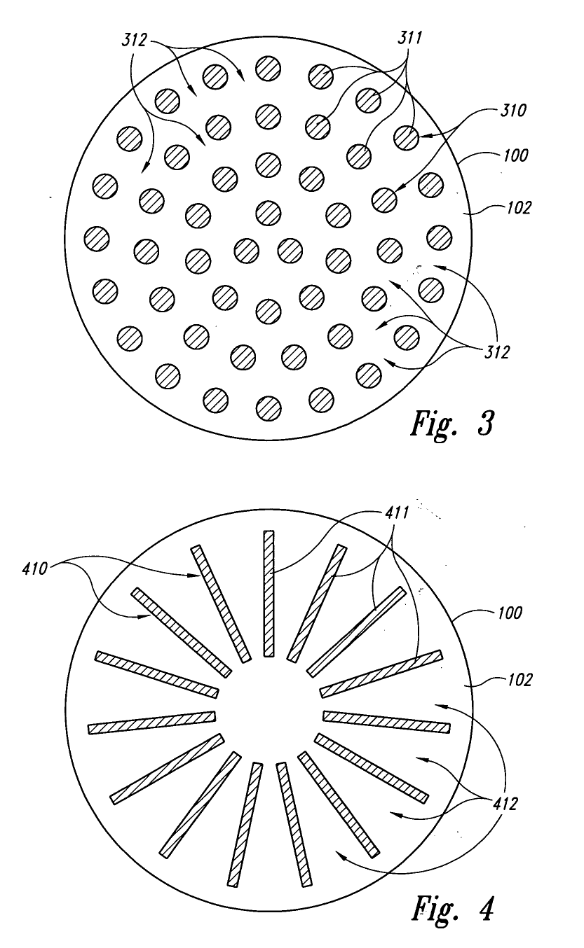

FIG. 3 is a top plan view of the first side 102 of the workpiece 100 in accordance with yet another embodiment of the invention. In this embodiment, a first adhesive 310 has been deposited onto the workpiece 100 in a pattern that includes a plurality of pads 311 separated by channels 312. The pads 311 can be round, rectilinear, polygonal, or other suitable shapes. In alternative embodiments, the pads 311 on a single workpiece can have different sizes and/or shapes.

FIG. 4 is a top plan view of the first side 102 of the workpiece 100 in accordance with still another embodiment of the invention. In this embodiment, a first adhesive 410 has been deposited onto the workpiece 100 in a plurality of rows 411 that extend radially outwardly from a center portion of the workpiece 100. The rows all are separated by channels 412. In additional embodiments, the first adhesive material may be deposited onto the workpiece 100 in other arrangements that include at least one gap separating pads of adhesive in a single radially orientated row in a manner similar to the gaps 213 in FIG. 2.

The first adhesive 210/310/410 in each of the foregoing embodiments can be generally similar to the materials described above with respect to FIGS. 1A-1G for the first adhesive 110. Further, the first adhesive 210/310/410 can be deposited onto the workpiece 100 in the desired pattern using methods similar to those described above, such as a pen-type dispensing method, a screen printing method, or another method known to those of skill in the art. In several embodiments, the methods of depositing an adhesive material onto a workpiece described above in FIGS. 2-4 may be used independently of the methods described above with respect to FIGS. 1A-1G regarding the application of the second adhesive. For example, a first adhesive material may be deposited onto a workpiece in a desired pattern in accordance with the methods described above in FIGS. 2-4 and the workpiece 100 can be releasably attached to a support member for further processing without applying a second adhesive to a perimeter portion of the workpiece.

From the foregoing, it will be appreciated that specific embodiments of the invention have been described herein for purposes of illustration, but that various modifications may be made without deviating from the spirit and scope of the invention. Accordingly, the invention is not limited except as by the appended claims.

I/We claim:

1. A method for processing a microfeature workpiece, comprising:
applying a first material to a first region on a first side of a microfeature workpiece;
releasably attaching the first side of the workpiece to a support member; and
applying a second material to a second region on the first side of the workpiece, the second region including a perimeter portion of the workpiece, wherein the second material is selectively removable from the workpiece relative to the first material, and wherein the first material and/or the second material is an adhesive.

2. The method of claim 1, further comprising:
removing the second material in a first environment after processing the workpiece; and
separating at least a portion of the workpiece from the support member by removing the first material in a second environment different than the first environment.

3. The method of claim 1 wherein:
applying a first material comprises applying a first material that has a first solubility in a solution; and
applying a second material comprises applying a second material that has a second solubility in the solution less than the first solubility.

4. The method of claim 1 wherein:
applying a first material comprises applying a first material that has a first solubility in an aqueous solution; and
applying a second material comprises applying a second material that has a second solubility less than the first solubility in an aqueous solution.

5. The method of claim 1 wherein:
applying a first material comprises applying a first material that is generally soluble in an aqueous solution; and
applying a second material comprises applying a second material that is generally insoluble in an aqueous solution.

6. The method of claim 1 wherein:
applying a first material to a first region comprises applying the first material to an interior portion of the first side of the workpiece; and
applying a second material to a second region comprises applying the second material in a gap between the workpiece and the support member at the second region.

7. The method of claim 1 wherein:
applying a first material to a first region comprises applying the first material in a pattern on the workpiece, the pattern including a plurality of rows with channels separating the individual rows from each other; and
applying a second material to a second region comprises applying the second material in a gap between the workpiece and the support member at the second region.

8. The method of claim 1 wherein:
applying a first material to a first region comprises applying the first material in a pattern on the workpiece, the pattern including a plurality of pads separated by channels; and
applying a second material to a second region comprises applying the second material in a gap between the workpiece and the support member at the second region.

9. The method of claim 8 wherein the pads include round, rectilinear, and/or polygonal pads.

10. The method of claim 1 wherein:
applying a first material to a first region comprises applying the first material in a pattern on the workpiece, the pattern including a plurality of rows separated by channels, the individual rows including a first block of the first material separated from a second block of the first material by a channel; and
applying a second material to a second region comprises applying the second material in a gap between the workpiece and the support member at the second region.

11. The method of claim 1 wherein applying a first material to a first region comprises screen printing the first material onto the first side of the workpiece.

12. The method of claim I wherein applying a second material to a second region comprises dispensing the second material in a gap between the workpiece and the support member at the second region.

13. The method of claim 1 wherein applying a material adhesive to a second region comprises screen printing the second material in a gap between the workpiece and the support member at the second region.

14. The method of claim 1 wherein applying a second material to a second region comprises caulking the second material in a gap between the workpiece and the support member at the second region.

15. The method of claim 1 wherein the workpiece has a first thickness, and wherein the method further comprises:
removing material from the workpiece to reduce a thickness of the workpiece from the first thickness to a second thickness less than the first thickness while the workpiece is carried by the support member.

16. The method of claim 1 wherein the workpiece has a first thickness and the support member has a second thickness, and wherein:
applying a first material to a first region on a first side of the workpiece comprises applying a layer of first material having a third thickness such that the aggregate thickness of the workpiece, support member, and first material is a desired thickness for further processing of the workpiece in the normal form factor of processing equipment used to process the workpiece.

17. The method of claim 1 wherein the workpiece has a first thickness and the support member has a second thickness, and wherein:
applying a first material to a first region on a first side of the workpiece comprises applying a layer of first material having a third thickness such that the aggregate thickness of the workpiece, support member, and first material is approximately 750 μm for further processing of the workpiece in the normal form factor of processing equipment used to process the workpiece.

18. A method for processing a microfeature workpiece, comprising:
applying a first adhesive to a first region on a first side of a microfeature workpiece having a first thickness, wherein the first region is an inner portion of the workpiece, and wherein the first adhesive is applied in a pattern having at least one channel separating individual portions of the first adhesive from each other;
releasably attaching the first side of the workpiece to a generally rigid support member;
applying a second adhesive to a second region on the first side of the microfeature workpiece, wherein the second region is a perimeter portion of the workpiece;
removing material from the workpiece to reduce a thickness of the workpiece from the first thickness to a second thickness less than the first thickness while the workpiece is releasably attached to the support member;
removing the second adhesive from the workpiece in a first environment after removing material from the workpiece; and
removing at least a portion of the workpiece from the support member by removing the first adhesive in a second environment different than the first environment.

19. The method of claim 18 wherein:
applying a first adhesive comprises applying a first adhesive that has a first solubility in a solution; and
applying a second adhesive comprises applying a second adhesive that has a second solubility in the solution less than the first solubility.

20. The method of claim 18 wherein:
applying a first adhesive comprises applying a first adhesive that has a first solubility in an aqueous solution; and
applying a second adhesive comprises applying a second adhesive that has a second solubility less than the first solubility in the aqueous solution.

21. The method of claim 18 wherein:
applying a first adhesive comprises applying a first adhesive that is generally soluble in an aqueous solution; and
applying a second adhesive comprises applying a second adhesive that is generally insoluble in an aqueous solution.

22. The method of claim 18 wherein:
applying a first adhesive comprises applying a first adhesive that is generally insoluble in an aqueous solution; and
applying a second adhesive comprises applying a second adhesive that is generally soluble in an aqueous solution.

23. A method for processing a microfeature workpiece, comprising:
providing a microfeature workpiece having a first side, a second side facing opposite the first side, and a first thickness between the first side and the second side;
providing a generally rigid support member having a second thickness;
applying a first material to an interior region on a first side of the workpiece and/or the support member, wherein the first material is applied in a pattern having at least one channel separating individual portions of the first material from each other, the first material having a third thickness;
releasably attaching the first side of the workpiece to the support member;
applying a second material in a gap between the workpiece and the support member at a perimeter region of the workpiece, the second material being removable from the workpiece in a different environment than the first material;
removing material from the workpiece to reduce a thickness of the workpiece from the first thickness to a fourth thickness less than the first thickness while the workpiece is releasably attached to the support member;
removing the second material from the workpiece in a first environment after removing material from the workpiece; and
removing at least a portion of the workpiece from the support member by removing the first material in a second environment different than the first environment.

24. The method of claim 23 wherein:
applying a first material comprises applying a first material that has a first solubility in a solution; and
applying a second material comprises applying a second material that has a second solubility in the solution less than the first solubility.

25. The method of claim 23 wherein:
applying a first material comprises applying a first material that has a first solubility in an aqueous solution; and
applying a second material comprises applying a second material that has a second solubility less than the first solubility in an aqueous solution.

26. A method for processing a microfeature workpiece, comprising:
depositing an adhesive material onto a microfeature workpiece in a pattern, the pattern including a first portion and a second portion spaced apart from each other by a channel;
releasably attaching the workpiece to a support member such that the adhesive is at least partially between the support member and the workpiece; and
removing at least a portion of the workpiece from the support member after processing the workpiece.

27. The method of claim 26 wherein depositing an adhesive material onto a microfeature workpiece in a pattern comprises depositing the adhesive in a plurality of generally parallel rows with channels separating the individual rows from each other.

28. The method of claim 26 wherein depositing an adhesive material onto a microfeature workpiece in a pattern comprises depositing the adhesive in a plurality of pads with gaps separating the individual pads from each other.

29. The method of claim 26 wherein depositing an adhesive material onto a microfeature workpiece in a pattern comprises depositing the adhesive in a plurality of rows separated by channels, the individual rows including a first block of the first material separated from a second block of the first material by a gap.

30. The method of claim 26 wherein depositing an adhesive material onto a microfeature workpiece in a pattern comprises screen printing the adhesive onto the workpiece.

31. A method for processing a microfeature workpiece, comprising:
depositing a first material onto a microfeature workpiece and/or a support member;
releasably attaching the workpiece to the support member; and
forming a barrier or seal around a perimeter gap between the workpiece and the support member, wherein the barrier is a formed from a different material than the first material.

32. A method for processing a microfeature workpiece, comprising:
forming a pattern of first material on a first side of a microfeature workpiece, the pattern including a first portion of first material and a second portion of first material spaced apart from each other by a gap;
releasably attaching the workpiece to a support member; and
applying a barrier material to a perimeter gap between the workpiece and the support member to protect the first material from a processing solution in which the first adhesive is generally soluble.

33. A method for processing a microfeature workpiece, comprising:
applying a first adhesive to an inner portion of a first side of a microfeature workpiece, the first adhesive being removable from the workpiece by a first release material, the first adhesive being in a pattern wherein a first portion of the first adhesive on the workpiece is spaced apart from a second portion of the first adhesive by a flow channel;
releasably attaching the first side of the workpiece to a generally rigid processing support member;
applying a second adhesive to a perimeter portion of the workpiece, the second adhesive being removable from the workpiece by a second release material different than the first release material, wherein the second adhesive protects the first adhesive from exposure to an outside environment and the first release material;.
after processing the workpiece, removing the second adhesive from the workpiece using the second release material; and
removing at least a portion of the workpiece from the processing support member by removing the first adhesive using the first release material, the first release material passing through at least a portion of the flow channel.

34. A microfeature assembly, comprising:
a microfeature workpiece having a first side and a second side facing opposite from the first side, the first side including a first region and a second region;
a first material on at least a portion of the first region of the workpiece, the first material having a first solubility in a solution;
a second material on at least a portion of the second region of the workpiece, the second region including a perimeter portion of the workpiece such that the second material substantially seals the first material from an outside environment, the second material having a second solubility in the solution less than the first solubility, and wherein the first material and/or the second material is an adhesive; and
a support member carried by the first side of the workpiece.

35. The assembly of claim 34 wherein:
the first material has a first solubility in an aqueous solution; and
the second material has a second solubility less than the first solubility in the aqueous solution.

36. The assembly of claim 34 wherein:
the first material is generally soluble in an aqueous solution; and
the second material is generally insoluble in an aqueous solution.

37. The assembly of claim 34 wherein:
the first material is generally insoluble in an aqueous solution; and
the second material is generally soluble in an aqueous solution.

38. The assembly of claim 34 wherein:
the first region is an interior portion of the first side of the workpiece;
the first material is on the first region in a pattern including a first portion of first material separated from a second portion of first material by a gap; and
the second material is in a gap between the workpiece and the support member at the second region.

39. The assembly of claim 34 wherein:
the first region is an interior portion of the first side of the workpiece;
the first material is on the first region in a pattern including a plurality of rows with channels separating the individual rows from each other; and
the second material is in a gap between the workpiece and the support member at the second region.

40. The assembly of claim 34 wherein:
the first region is an interior portion of the first side of the workpiece;
the first material is on the first region in a pattern including a plurality of pads separated by gaps; and
the second material is in a gap between the workpiece and the support member at the second region.

41. The assembly of claim 40 wherein the pads include round, rectilinear, and/or polygonal pads.

42. The assembly of claim 34 wherein:
the workpiece has a first thickness;
the support member has a second thickness; and
the first material has a third thickness such that the aggregate thickness of the workpiece, support member, and first material is a desired thickness for further processing of the workpiece in the normal form factor of processing equipment used to process the workpiece.

43. The assembly of claim 34 wherein:
the workpiece has a first thickness;
the support member has a second thickness; and
the first material has a third thickness such that the aggregate thickness of the workpiece, support member, and first material is approximately 750 μm for further processing of the workpiece in the normal form factor of processing equipment used to process the workpiece.

44. A microfeature assembly, comprising:
a microfeature workpiece having a first side and a second side facing opposite from the first side, the first side including an inner region and a perimeter region;
a first material on at least a portion of the inner region of the workpiece, the first material being arranged in a pattern including a first portion of the first adhesive separated from a second portion of the first adhesive by a gap, the first material being removable from the workpiece by a first release material;
a second material on at least a portion of the perimeter region of the workpiece such that the second adhesive substantially seals the first adhesive from an outside environment, the second material being removable from the workpiece by a second release material different than the first release material, wherein the first material and/or the second material is an adhesive; and
a generally rigid support member releasably attached to the first side of the microfeature workpiece by the first material and/or the second material.

45. The assembly of claim 44 wherein the pattern of first material on the workpiece comprises a plurality of rows with channels separating the individual rows from each other.

46. The assembly of claim 44 wherein the pattern of first material on the workpiece comprises a plurality of pads with gaps separating the individual pads from each other.

47. The assembly of claim 46 wherein the pads include round, rectilinear, and/or polygonal pads.

48. The assembly of claim 44 wherein the pattern of first material on the workpiece comprises a plurality of rows extending radially outward from a center portion of the workpiece with channels separating the individual rows from each other.

49. The assembly of claim 44 wherein:
the workpiece has a first thickness;
the support member has a second thickness; and
the first material has a third thickness such that the aggregate thickness of the workpiece, support member, and first material is a desired thickness for further processing of the workpiece in the normal form factor of processing equipment used to process the workpiece.

50. The assembly of claim 44 wherein:
the workpiece has a first thickness;
the support member has a second thickness; and
the first material has a third thickness such that the aggregate thickness of the workpiece, support member, and first material is approximately 750 μm for further processing of the workpiece in the normal form factor of processing equipment used to process the workpiece.

51. A microfeature assembly, comprising:
a microfeature workpiece having a first side and a second side facing opposite from the first side; and
an adhesive material on at least a portion of the first side in a pattern, the pattern including a first portion of the adhesive spaced apart from a second portion of the adhesive.

52. The assembly of claim 51 wherein the pattern of adhesive material on the workpiece comprises a plurality of rows with channels separating the individual rows from each other.

53. The assembly of claim 51 wherein the pattern of adhesive material on the workpiece comprises a plurality of pads with gaps separating the individual pads from each other.

54. The assembly of claim 53 wherein the pads include round, rectilinear, and/or polygonal pads

55. The assembly of claim 51 wherein the pattern of adhesive material on the workpiece comprises a plurality of rows extending radially outward from a center portion of the workpiece with channels separating the individual rows from each other.
